(19) United States
(12) Patent Application Publication
(10) Pub. No.: US 2026/0123397 A1
(43) Pub. Date: Apr. 30, 2026

(54) GATE CONTACT STRUCTURE AND METHOD OF MANUFACTURING THE SAME

(71) Applicant: Samsung Electronics Co., Ltd., Suwon-si (KR)

(72) Inventors: Deokhwan KIM, Suwon-si (KR); Sungmin KIM, Suwon-si (KR); Jaemyeong KIM, Suwon-si (KR); Jeonggeol KIM, Suwon-si (KR); Yongkyung LEE, Suwon-si (KR)

(73) Assignee: Samsung Electronics Co., Ltd., Suwon-si (KR)

(21) Appl. No.: 19/357,157

(22) Filed: Oct. 14, 2025

(30) Foreign Application Priority Data
Oct. 30, 2024 (KR) 10-2024-0151495

(51) Int. Cl. H01L 23/532; H01L 21/768; H01L 23/522; H10D 30/62

(52) U.S. Cl. CPC H10W 20/47; H10W 20/033; H10W 20/072; H10W 20/42; H10W 20/46; H10D 30/62

(57) ABSTRACT

Provided are a gate contact structure and a method of manufacturing the gate contact structure. The gate contact structure includes a gate electrode, an etch stop layer on the gate electrode, a capping layer on the etch stop layer, the etch stop layer and the capping layer defining a contact hole penetrating therethrough, the contact hole including a first portion and a second portion, the first portion being in the etch stop layer and exposing the gate electrode, and the second portion being in the capping layer and in communication with the first portion, a liner along a side of the contact hole, and a gate contact plug being within the liner, wherein the etch stop layer, the gate electrode, and the liner define an air gap adjacent to the first portion of the contact hole.

### CROSS-REFERENCE TO RELATED APPLICATION

This application is based on and claims priority under 35 U.S.C. § 119 to Korean Patent Application No. 10-2024-0151495, filed on Oct. 30, 2024, in the Korean Intellectual Property Office, the disclosure of which is incorporated by reference herein in its entirety.

### BACKGROUND

### 1. Field

The disclosure relates to gate contact structures and methods of manufacturing the same, and more particularly, to contact structures of a gate electrode and a gate contact plug and methods of manufacturing the contact structure.

### 2. Description of the Related Art

In the electronics industry, the demand for smaller, faster electronic devices capable of simultaneously supporting numerous functions continues to increase. Accordingly, the semiconductor industry continues to pursue the trend toward manufacturing lower-cost, higher-performance, and/or lower-power integrated circuits (ICs). Up to now, such goals have been largely achieved by reducing semiconductor IC dimensions (e.g., a minimum feature size) to improve the production efficiency and/or lower the associated costs. However, this expansion has complicated the semiconductor manufacturing processes. Therefore, for continuous advancements in semiconductor ICs and devices, similar advancements in semiconductor manufacturing processes and technologies are desired.

As IC devices continue to become smaller, the dimensions of contact features such as source/drain contact vias and/or gate contact features are becoming smaller, and parasitic capacitance occurs between the source/drain contact plug and the gate contact plug in proportion to a dielectric constant of a capping layer. Therefore, there is a need for a gate contact structure capable of implementing lower-power, higher-speed operation of a device while lowering the contact resistance, and/or a method of manufacturing the gate contact structure.

### SUMMARY

Provided are gate contact structures with an air gap adjacent to a contact hole of a semiconductor structure to improve parasitic capacitance between a source/drain contact plug and a gate contact plug in proportion to a dielectric constant of a capping layer and/or methods of manufacturing the gate contact structure.

Additional aspects will be set forth in part in the description which follows and, in part, will be apparent from the description, or may be learned by practice of the presented example embodiments of the disclosure.

According to an example embodiment of the disclosure, a gate contact structure may include a gate electrode, an etch stop layer on the gate electrode, a capping layer on the etch stop layer, the etch stop layer and the capping layer defining a contact hole penetrating therethrough, the contact hole including a first portion and a second portion, the first portion being in the etch stop layer and exposing the gate electrode, the second portion being in the capping layer and in communication with the first portion, a liner along a side of the contact hole, and a gate contact plug being within the liner, wherein the etch stop layer, the gate electrode, and the liner define an air gap adjacent to the first portion of the contact hole.

The liner may include a first extension portion on the gate electrode and a second extension portion connected to one end of the first extension portion and extending to surround the air gap.

The second extension portion may be provided to be in contact with one surface of the capping layer.

The second extension portion may be provided to be in contact with one surface of the capping layer and one surface of a gate cut perpendicular to the one surface of the capping layer.

The gate contact plug may include a barrier metal and a metal material, the barrier metal may be on one surface of the gate electrode, and the air gap is on the barrier metal.

The capping layer may include SiN, and the etch stop layer may include at least one of SiO₂, SiOCN, SiON, SiOC, SiCN, or a combination thereof.

The liner may include SiN, and the etch stop layer may include at least one of SiO₂, SiOCN, SiON, SiOC, SiCN, or a combination thereof.

According to an example embodiment of the disclosure, provided is a method of manufacturing a method of manufacturing a gate contact structure, the method including preparing an etch stop layer on a gate electrode, preparing a capping layer on the etch stop layer, forming a first portion of a contact hole by etching the capping layer, forming a second portion of the contact hole by etching the etch stop layer such that a part of the etch stop layer remains, depositing a liner within the contact hole, forming an air gap adjacent to the second portion of the contact hole, and forming a gate contact plug within the contact hole in which the liner is deposited.

The forming of the air gap may include forming an opening communicating with the second portion of the contact hole and in contact with one surface of the gate electrode by etching the etch stop layer and closing the opening to form the air gap by additionally depositing the liner on the one surface of the gate electrode.

The forming of the air gap may include forming an opening communicating with the second portion of the contact hole and in contact with one surface of the gate electrode and one surface of the capping layer by etching the etch stop layer and closing the opening to form the air gap by additionally depositing the liner on the one surface of the gate electrode.

The forming of the air gap may include forming an opening communicating with the second portion of the contact hole and in contact with one surface of the gate electrode, one surface of the capping layer, and one surface of a gate cut perpendicular to the one surface of the capping layer by etching the etch stop layer, and closing the opening to form the air gap by depositing the liner on the one surface of the gate electrode.

The forming of the air gap may include forming an opening communicating with the second portion of the contact hole and in contact with one surface of the gate electrode by etching the etch stop layer and closing the opening to form the air gap by depositing a barrier metal on the one surface of the gate electrode.

The capping layer may include SiN, and the etch stop layer may include at least one of SiO₂, SiOCN, SiON, SiOC, SiCN, or a combination thereof.

The liner may include SiN, and the etch stop layer may include at least one of SiO₂, SiOCN, SiON, SiOC, SiCN, or a combination thereof.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a diagram schematically illustrating an overall configuration of a semiconductor structure according to an example embodiment;

FIG. 2 is a gate cut cross-sectional view of a gate contact structure according to an example embodiment;

FIGS. 3A to 10 are diagrams illustrating a method of manufacturing the gate contact structure of FIG. 2;

FIG. 11 is a gate cut cross-sectional view of a gate contact structure according to another example embodiment;

FIG. 12 is a gate cut cross-sectional view of a gate contact structure according to another example embodiment; and

FIG. 13 is a gate cut cross-sectional view of a gate contact structure according to another example embodiment.

### DETAILED DESCRIPTION

Reference will now be made in detail to example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, a gate contact structure and a method of manufacturing the same will be described in detail with reference to the accompanying drawings. Some example embodiments described herein are only examples and various modifications may be made thereto from these example embodiments. In the following drawings, the same reference numerals denote the same elements, and the size of each element in the drawings may be exaggerated for clarity and convenience of explanation.

Hereinafter, the terms “above” or “on” may include not only those that are directly above, below, left, or right in a contact manner, but also those that are above, below, left, or right in a non-contact manner.

The terms such as “first,” “second,” etc. may be used to describe various elements, but are only used to distinguish one element from another element. These terms are not intended to limit different materials or structures of the elements.

The singular forms as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

Also, the terms such as “unit” and “module” described in the specification mean units that process at least one function or operation, and may be implemented as hardware, software, or a combination of hardware and software.

The use of the term “the” and similar demonstratives may correspond to both the singular and the plural. Also, the use of all illustrations or illustrative terms (for example, etc.) in the example embodiments is simply to describe the technical ideas in detail, and the scope of the disclosure is not limited by the illustrations or illustrative terms unless they are limited by claims.

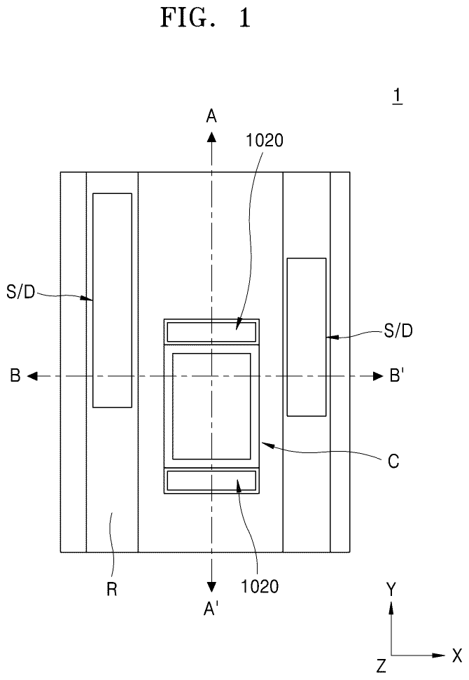

FIG. 1 is a diagram schematically illustrating an overall configuration of a semiconductor structure 1 according to an example embodiment.

Referring to FIG. 1, the semiconductor structure 1 may include source/drain electrodes S/D and a gate contact plug C. The source/drain electrodes S/D may be apart from each other in an X direction. Source/drain regions may be provided below the source/drain electrodes S/D. The gate contact plug C may be provided between the source/drain electrodes S/D. An air gap 1020 may be provided adjacent to one end and the other end of the gate contact plug C in a Y direction. A channel may be provided between source/drain regions R. On the other hand, the source/drain electrodes S/D and the gate contact plug C may be provided in various layouts. For example, as illustrated in FIG. 1, one of the source/drain electrodes S/D and the gate contact plug C may be provided at different levels in a Y direction, and the other of the source/drain electrodes S/D may be provided at a level between the one of the source/drain electrodes S/D and the gate contact plug C in the Y direction. This is only an example and the source/drain electrodes S/D and the gate contact plug C may be formed in various layouts. Hereinafter, the gate contact plug C, the gate electrode, and the components related thereto are mainly described. Hereinafter, a cross-section taken along line A-A′ of FIG. 1 is referred to as a gate cut and a cross-section taken along line B-B′ of FIG. 1 is referred to as an active cut.

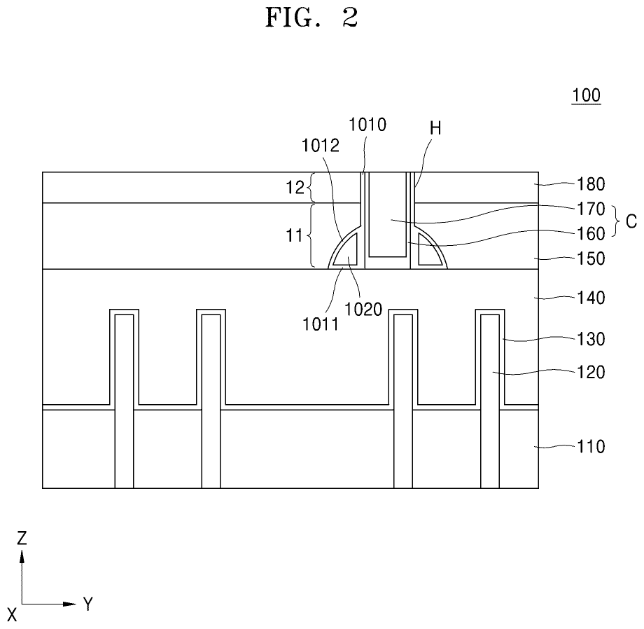

FIG. 2 is a gate cut cross-sectional view of a gate contact structure 100 according to an example embodiment. For convenience of explanation, some elements are omitted.

Referring to FIG. 2, the gate contact structure 100 according to an example embodiment may include a channel 120 provided on a substrate 110, an insulating layer 130 provided on the channel 120, and a gate electrode 140 provided on the insulating layer 130. In addition, an etch stop layer 150 may be provided on the gate electrode 140 and a capping layer 180 may be provided on the etch stop layer 150.

The substrate 110 may be an insulating substrate, or may be a semiconductor substrate with an insulating material formed on a surface thereof. In some example embodiments, the substrate 110 may be a semiconductor substrate. The semiconductor substrate may include, for example, Si, Ge, SiGe, or a Group III-V semiconductor material. The substrate 110 may be, for example, a silicon substrate having silicon oxide formed on a surface thereof, but example embodiments of the disclosure are not limited thereto.

The channel 120 may include an amorphous oxide semiconductor. The channel 120 may include a material selected from, for example, InGaZnO, ZrInZnO, InZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAIO₂, CuGaO₂, Nb₂O₅, TiSrO₃, zinc indium oxide (ZIO), indium gallium oxide (IGO), and any combination thereof. The channel 120 may be, for example, a fin channel extending in a direction perpendicular to the substrate 110. Hereinafter, a fin field effect transistor (FinFET) structure is described as an example, but the following description may also be applied to various structures, including a gate-all-around (GAA) structure.

The gate electrode 140 may include at least one conductive material of (or selected from) metal, metal nitride, metal carbide, polysilicon, or any combination thereof. For example, the metal may include aluminum (Al), tungsten (W), molybdenum (Mo), titanium (Ti), or tantalum (Ta), the metal nitride film may include a titanium nitride (TiN) film or a tantalum nitride (TaN) film, and the metal carbide may include TiAlC, TaAlC, TiSiC, or TaSiC.

The insulating layer 130 may be provided between the channel 120 and the gate electrode 140 to electrically disconnect the channel 120 and the gate electrode 140 from each other. The insulating layer 130 may include an insulating material. The insulating layer 130 may include, for example, a dielectric. The insulating layer 130 may include, for example, a high-k material, such as aluminum oxide, hafnium (Hf) oxide, or titanium oxide, but example embodiments of the disclosure are not limited thereto.

The etch stop layer 150 may include a material having a significantly different etch rate with respect to the capping layer 180. The etch stop layer 150 may include a material having an etching selectivity with respect to the capping layer 180. For example, the capping layer 180 may include silicon nitride. For example, the capping layer 180 may include SiN. For example, the etch stop layer 150 may include at least one selected from SiO₂, SiOCN, SiON, SiOC, SiCN, and any combination thereof.

A contact hole H passing through the etch stop layer 150 and the capping layer 180 in a Z direction may be provided. The contact hole H may include a first portion 11 passing through the etch stop layer 150 and a second portion 12 passing through the capping layer 180 and communicating with the first portion 11. A lower part of the first portion 11 may be provided between the gate electrode 140 and the etch stop layer 150. The first portion 11 of the contact hole H may extend from a lower portion to an upper portion of the etch stop layer 150 in the third direction (Z direction). The second portion 12 of the contact hole H may extend from a lower portion to an upper portion of the capping layer 180 in the third direction (Z direction).

A liner 1010 may extend in the third direction (Z direction) along an inner surface defining the contact hole H, and may be provided from the upper portion of the capping layer 180 to an upper surface of the gate electrode 140. In addition, a first extension portion 1011 and a second extension portion 1012 of the liner 1010 may be provided to form the air gap 1020 adjacent to the first portion 11 of the contact hole H. For example, the first extension portion 1011 of the liner 1010 may be provided on the gate electrode 140. One end of the first extension portion 1011 may be provided at a part of the liner 1010 provided along the inner surface defining the contact hole H and in contact with the gate electrode 140, and the other end of the first extension portion 1011 of the liner 1010 may extend from the one end of the first extension portion 1011 to both sides of the contact hole H in the second direction (Y direction). The first extension portion 1011 may be provided to be in contact with the gate electrode 140. In addition, the second extension portion 1012 may be provided to extend from the other end of the first extension portion 1011 and be connected to a point having a certain height in the liner 1010, which is provided along the inner surface defining the contact hole H, from the gate electrode 140 in the third direction (Z direction).

The liner 1010, the first extension portion 1011, and the second extension portion 1012 provided on the inner surface defining the contact hole H may form a closed curved surface adjacent to the first portion 11 of the contact hole H. The air gap 1020 may be formed inside the closed curved surface formed by the liner 1010, the first extension portion 1011, and the second extension portion 1012. The air gap 1020 may be provided at both sides of the contact hole H in the second direction (Y direction). The liner 1010, the first extension portion 1011, and the second extension portion 1012 may each include a material having an etching selectivity with respect to the etch stop layer 150. The liner 1010, the first extension portion 1011, and the second extension portion 1012 may each include, for example, the same constituent material as that of the capping layer 180. The liner 1010, the first extension portion 1011, and the second extension portion 1012 may each include, for example, SiN. In some example embodiments, the liner 1010, the first extension portion 1011, and the second extension portion 1012 may each include a different constituent material from that of the capping layer 180. The air gap 1020 may include air or vacuum.

The gate contact plug C may be provided inside the liner 1010 provided on the inner surface defining the contact hole H. The gate contact plug C may include a barrier metal 160 and a metal material 170 provided inside the barrier metal 160 described above. The barrier metal 160 may include, for example, Ti or TIN. The metal material 170 may include, for example, W.

The gate contact structure 100 according to an example embodiment may form the air gap 1020 adjacent to the contact hole H through a process of a method of manufacturing the gate contact structure 100 to be described below by providing the etch stop layer 150 having an etching selectivity with respect to the capping layer 180 between the capping layer 180 and the gate electrode 140. The air gap 1020 adjacent to the contact hole H is provided, and thus parasitic capacitance between the source/drain contact plug and the gate contact plug C in proportion to the dielectric constant of the capping layer 180 may be improved (e.g., reduced).

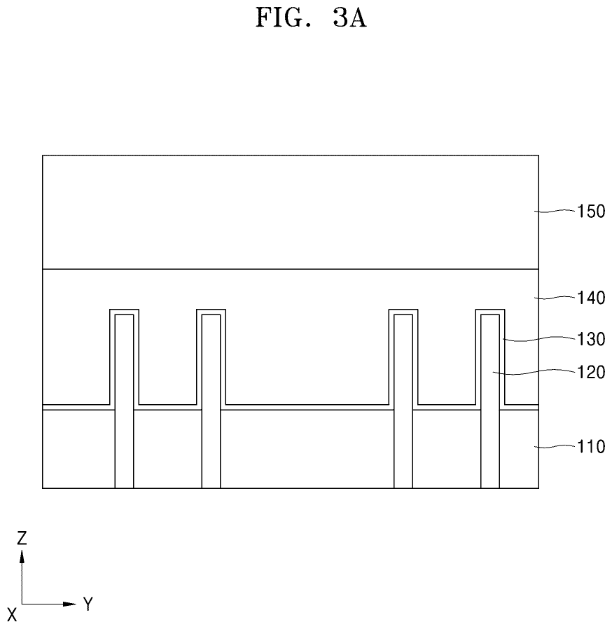

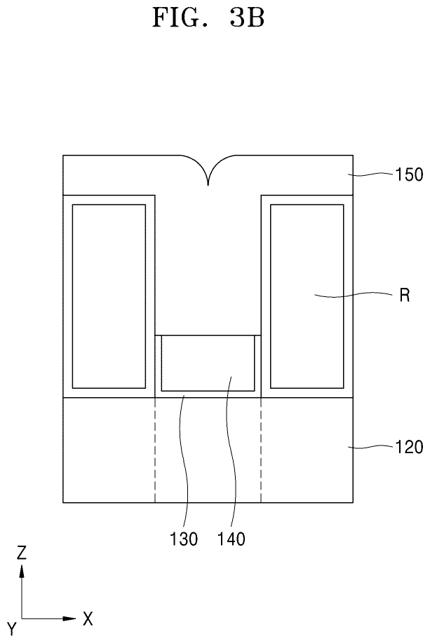

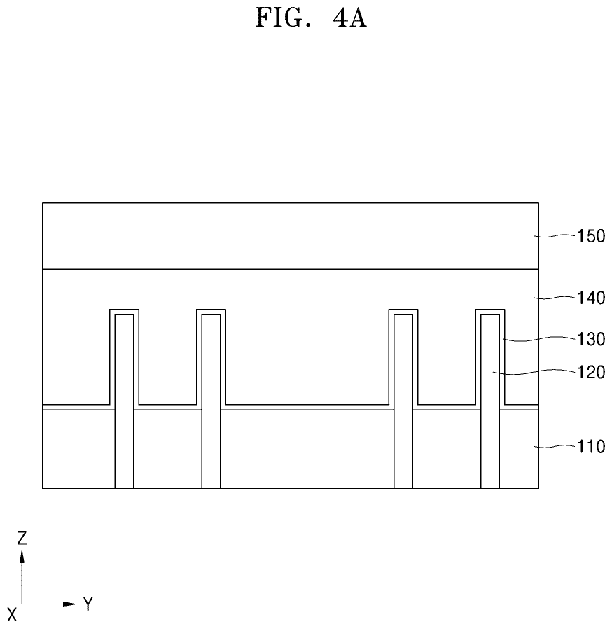

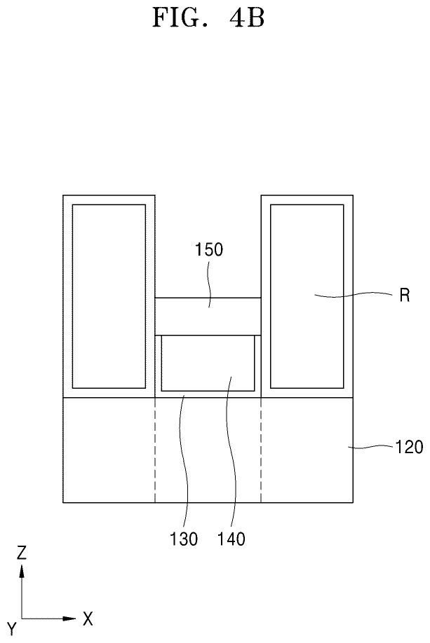

FIGS. 3A to 10 are diagrams illustrating a method of manufacturing a gate contact structure of FIG. 2. FIG. 3B is an active cut cross-sectional view corresponding to a gate cut cross-sectional view of FIG. 3A. FIG. 4B is an active cut cross-sectional view corresponding to a gate cut cross-sectional view of FIG. 4A.

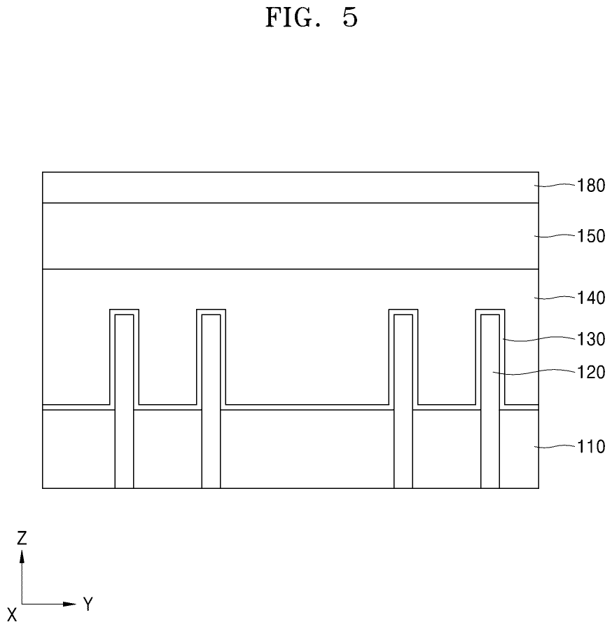

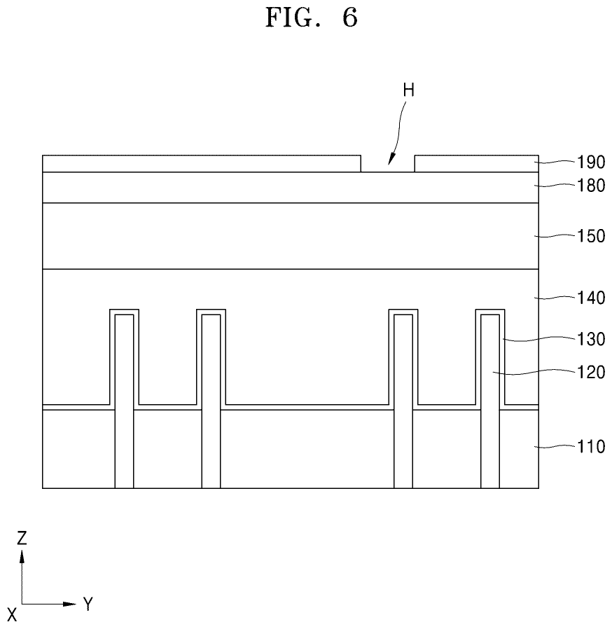

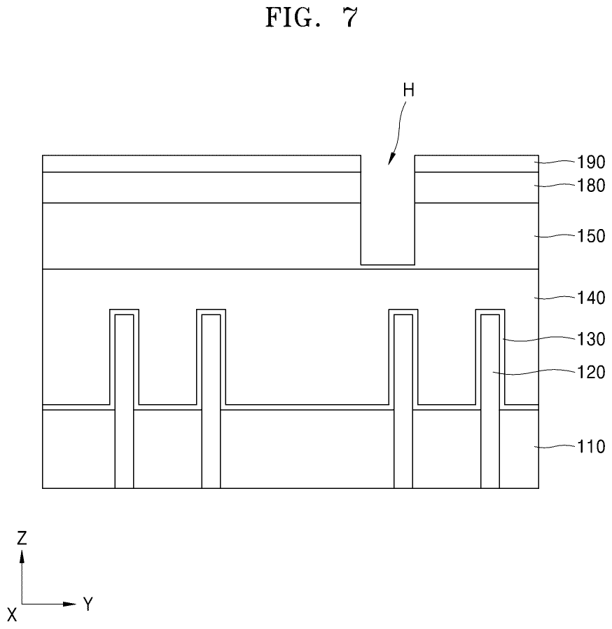

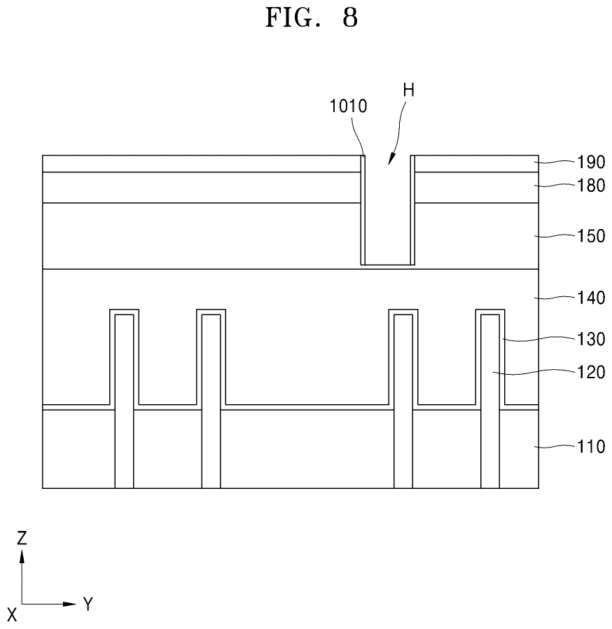

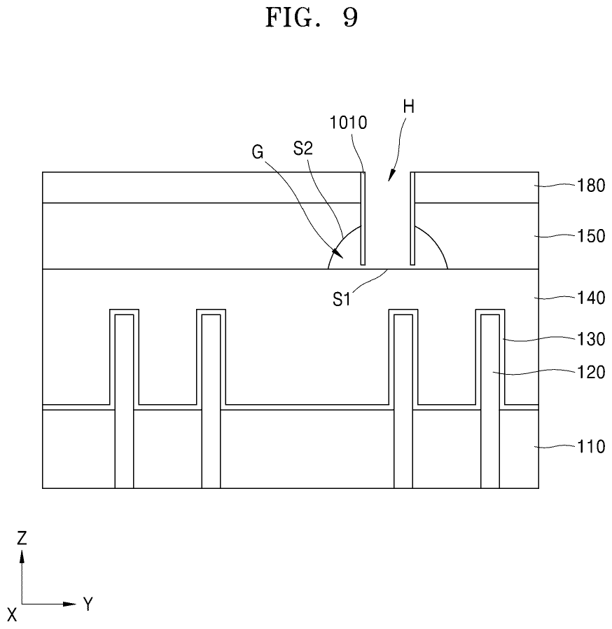

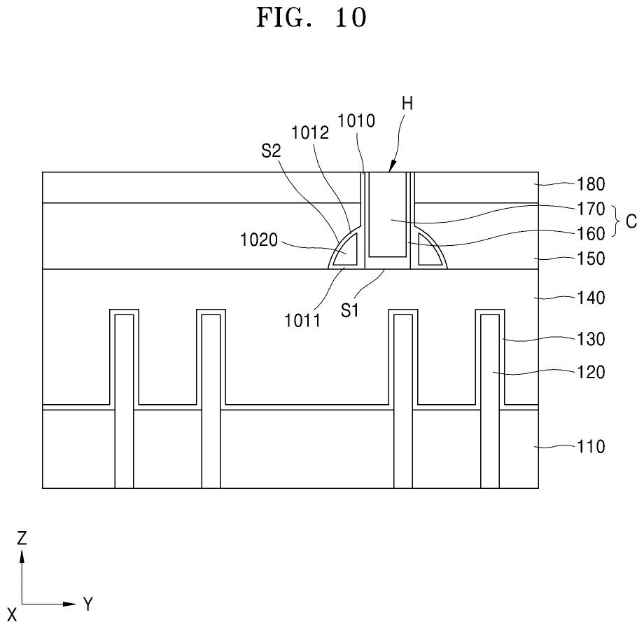

Referring to FIGS. 3A and 3B, the channel 120, the insulating layer 130, and the gate electrode 140 are provided on the substrate 110, and the etch stop layer 150 is deposited on the gate electrode 140. At this time, as shown in FIG. 3B, the etch stop layer 150 may be deposited on the gate electrode 140 while being folded. Referring to FIGS. 4A and 4B, the etch stop layer 150 deposited on the gate electrode 140 is partially etched up to a certain height in the Z direction. Referring to FIG. 5, the capping layer 180 is formed on the etch stop layer 150. Referring to FIG. 6, an etching mask 190 with a pattern for selectively etching the etch stop layer 150 and the capping layer 180 is provided on the capping layer 180. Referring to FIG. 7, the capping layer 180 and the etch stop layer 150 provided below the etching mask 190 are anisotropically etched according to the pattern of the etching mask 190 such that a part of the etch stop layer 150 remains. The capping layer 180 and the etch stop layer 150 may be etched in the third direction (Z direction) according to the pattern of the etching mask 190 such that the contact hole H may be provided. Referring to FIG. 8, the liner 1010 is deposited on an inner surface defining the contact hole H to extend in the third direction (Z direction). After the liner 1010 is deposited, an etching process may be additionally performed. Referring to FIG. 9, the etch stop layer 150 is isotropically etched. The etch stop layer 150 may be etched such that a first surface S1, which is a part of an upper surface of the gate electrode 140, is exposed. The inside of the etch stop layer 150 may be etched from the gate electrode 140 to a point with a certain height in the third direction (Z direction) such that the second surface S2 may be exposed. At this time, the liner 1010 and the etch stop layer 150 may include materials having an etching selectivity to each other so that only the etch stop layer 150 may be etched, and the liner 1010 may not be etched. As the etch stop layer 150 is etched, an opening G including the liner 1010, the first surface S1, and the second surface S2 may be provided. Referring to FIG. 10, the liner 1010 may be additionally deposited to form the first extension portion 1011 of the liner 1010 along the first surface S1, and to form the second extension portion 1012 of the liner 1010 along the second surface S2. In this case, the liner 1010 may be additionally deposited until an entrance of the opening G is blocked or closed. As the entrance of the opening G is blocked or closed, the air gap 1020 adjacent to the contact hole H in the second direction (Y direction) may be formed. After additional deposition of the liner 1010, an etching process may be additionally performed. Thereafter, the barrier metal 160 and the metal material 170 may be provided in the contact hole H to form the gate contact plug C.

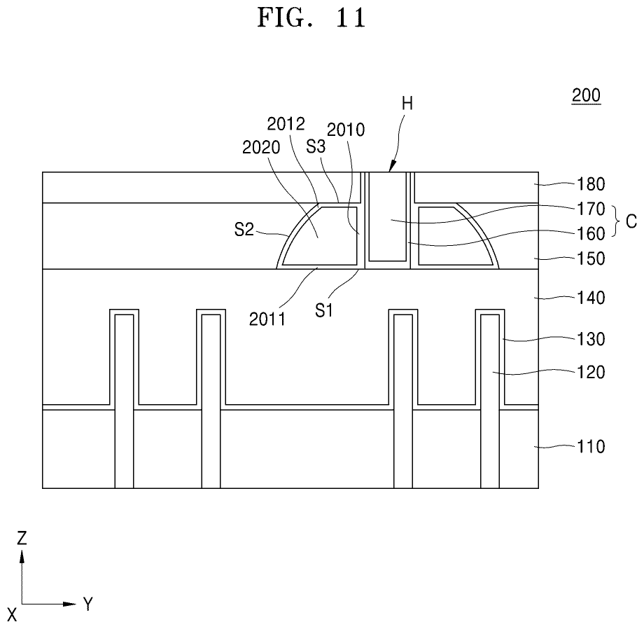

FIG. 11 is a gate cut cross-sectional view of a gate contact structure 200 according to another example embodiment. The differences from FIG. 2 will be mainly described, and the same reference numerals denote the same components.

Referring to FIG. 11, the etch stop layer 150 may be isotropically etched to expose a third surface S3, which is a part of a lower surface of the capping layer 180, as compared with FIG. 2. Thereafter, a liner 2010 may be deposited to block or close an entrance of an opening communicating with the contact hole H, and form an air gap 2020.

As described above, the air gap 2020 may be formed and expanded by depositing the liner 2010 while the etch stop layer 150 is further isotropically etched, and a second extension portion 2012 of the liner 2010 may be provided to contact the lower surface of the capping layer 180 as shown in FIG. 11.

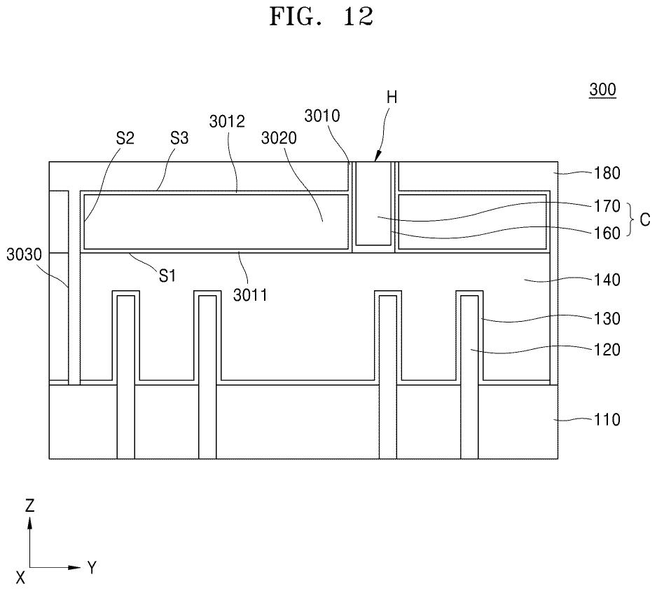

FIG. 12 is a gate cut cross-sectional view of a gate contact structure according to another example embodiment. The differences will be mainly described with reference to FIG. 11, and the same reference numerals denote the same elements.

Referring to FIG. 12, the etch stop layer 150 may be etched such that the first surface S1 of the opening communicating with the contact hole H is provided on the entire upper portion of the gate electrode 140, the second surface S2 is provided on one surface of a gate cut material 3030 perpendicular to one surface of the gate electrode 140, and the third surface S3 is provided on the entire lower surface of the capping layer 180, as compared with FIG. 11. The etch stop layer 150 on the gate electrode 140 may be completely removed. While the etch stop layer 150 is removed, a liner 3010 may be deposited to block or close an entrance of an opening communicating with the contact hole H and form an air gap 3020.

As described above, the air gap 3020 may be formed and expanded to the entire upper portion of the gate electrode 140 by depositing the liner 3010 while the etch stop layer 150 is completely isotropically etched, and as shown in FIG. 12, a first extension portion 3011 of the liner 3010 may be in contact with an upper surface of the gate electrode 140, and a second extension portion 3012 may be provided to be in contact with both the lower surface of the capping layer 180 and one surface of the gate cut material 3030 described above.

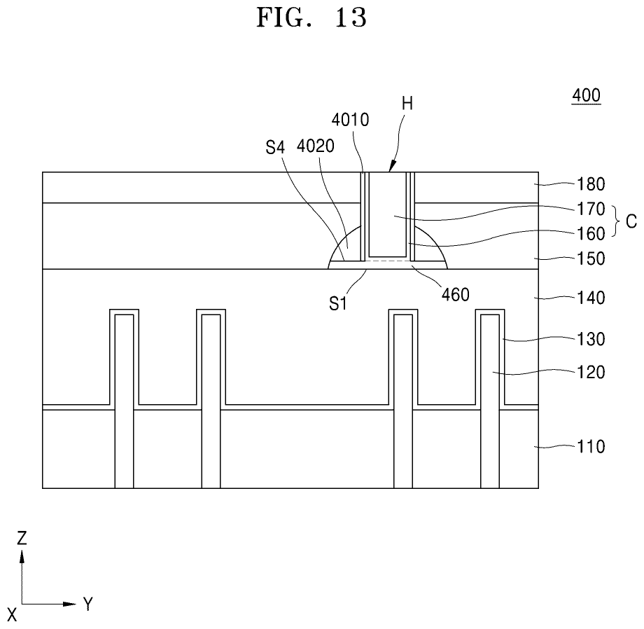

FIG. 13 is a gate cut cross-sectional view of a gate contact structure 400 according to another example embodiment. The differences will be mainly described with reference to FIG. 2, and the same reference numerals denote the same elements.

Referring to FIG. 13, as compared with FIG. 2, an air gap 4020 may be formed by first selectively depositing a part of the gate contact plug C after the etch stop layer 150 is isotropically etched.

For example, after forming the opening communicating with the contact hole (H) by isotropically etching the etch stop layer 150, a part 460 of the barrier metal 160 may be selectively deposited first on the first surface S1, which is the upper surface of the gate electrode 140. The part 460 of the barrier metal 160 may be first grown to a fourth surface S4 to block or close an entrance of the opening communicating with the contact hole H, and form the air gap 4020. Thereafter, the remaining barrier metal 160 and metal material 170 may be provided in the contact hole H to form the gate contact plug C.

The gate contact structure and the method of manufacturing the same according to an example embodiment may form the air gap adjacent to the contact hole by providing (1) the etch stop layer having an etching selectivity with respect to the capping layer and (2) the liner between the capping layer and the gate electrode. Therefore, parasitic capacitance between the source/drain contact plug and the gate contact plug may be improved (e.g., reduced).

It should be understood that the example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A gate contact structure comprising:
a gate electrode;
an etch stop layer on the gate electrode;
a capping layer on the etch stop layer;
the etch stop layer and the capping layer defining a contact hole penetrating therethrough, the contact hole comprising a first portion and a second portion, the first portion being in the etch stop layer and exposing the gate electrode, the second portion being in the capping layer and in communication with the first portion;
a liner along a side of the contact hole; and
a gate contact plug being within the liner,
wherein the etch stop layer, the gate electrode, and the liner define an air gap adjacent to the first portion of the contact hole.

2. The gate contact structure of claim 1, wherein the liner includes:
a first extension portion on the gate electrode; and
a second extension portion connected to one end of the first extension portion and extending to surround the air gap.

3. The gate contact structure of claim 2, wherein the second extension portion is in contact with one surface of the capping layer.

4. The gate contact structure of claim 2, wherein the second extension portion is in contact with one surface of the capping layer and one surface of a gate cut perpendicular to the one surface of the capping layer.

5. The gate contact structure of claim 1, wherein
the gate contact plug includes a barrier metal and a metal material,
the barrier metal is on one surface of the gate electrode, and
the air gap is on the barrier metal.

6. The gate contact structure of claim 1, wherein the capping layer includes SiN, and the etch stop layer includes at least one of SiO₂, SiOCN, SiON, SiOC, SiCN, or combinations thereof.

7. The gate contact structure of claim 1, wherein the liner includes SiN, and the etch stop layer includes at least one of SiO₂, SiOCN, SiON, SiOC, SiCN, or combinations thereof.

8. A method of manufacturing a gate contact structure, the method comprising:
preparing an etch stop layer on a gate electrode;
preparing a capping layer on the etch stop layer;
forming a first portion of a contact hole by etching the capping layer;
forming a second portion of the contact hole by etching the etch stop layer such that a part of the etch stop layer remains;
depositing a liner within the contact hole;
forming an air gap adjacent to the second portion of the contact hole; and
forming a gate contact plug within the contact hole in which the liner is deposited.

9. The method of claim 8, wherein the forming of the air gap includes
forming an opening communicating with the second portion of the contact hole and in contact with one surface of the gate electrode by etching the etch stop layer; and
closing the opening to form the air gap by additionally depositing the liner on the one surface of the gate electrode.

10. The method of claim 8, wherein the forming of the air gap includes
forming an opening communicating with the second portion of the contact hole and in contact with one surface of the gate electrode and one surface of the capping layer by etching the etch stop layer; and
closing the opening to form the air gap by additionally depositing the liner on the one surface of the gate electrode.

11. The method of claim 8, wherein the forming of the air gap includes
forming an opening communicating with the second portion of the contact hole and in contact with one surface of the gate electrode, one surface of the capping layer, and one surface of a gate cut perpendicular to the one surface of the capping layer by etching the etch stop layer; and
closing the opening and forming the air gap by additionally depositing the liner on the one surface of the gate electrode.

12. The method of claim 8, wherein the forming of the air gap includes
forming an opening communicating with the second portion of the contact hole and in contact with one surface of the gate electrode by etching the etch stop layer; and
closing the opening to form the air gap by depositing a barrier metal on the one surface of the gate electrode.

13. The method of claim 8, wherein the capping layer includes SiN, and the etch stop layer includes at least one of SiO₂, SiOCN, SiON, SiOC, SiCN, or combinations thereof.

14. The method of claim 8, wherein the liner includes SiN, and the etch stop layer includes at least one of SiO₂, SiOCN, SiON, SiOC, SiCN, or combinations thereof.
